(19) United States
(12) Patent Application Publication
(10) Pub. No.: US 2026/0293225 A1
(43) Pub. Date: Sep. 24, 2026

(54) SEMICONDUCTOR DEVICE

(71) Applicants: Kabushiki Kaisha Toshiba, Kanagawa (JP); Toshiba Electronic Devices & Storage Corporation, Kanagawa (JP)

(72) Inventor: Masaru Furukawa, Himeji Hyogo (JP)

(21) Appl. No.: 19/312,117

(22) Filed: Aug. 27, 2025

(30) Foreign Application Priority Data
Mar. 24, 2025 (JP) 2025-048590

(51) Int. Cl. H10D 62/10; H10D 30/66; H10D 62/60; H10D 62/832

(52) U.S. Cl. CPC H10D 62/102; H10D 30/665; H10D 62/124; H10D 62/60; H10D 62/8325

(57) ABSTRACT

According to one embodiment, a semiconductor device includes a first electrode, a first semiconductor region of a first conductivity type, a second semiconductor region of a second conductivity type, a third semiconductor region of the first conductivity type, a gate electrode, a fourth semiconductor region of the second conductivity type, and a second electrode. The gate electrode faces the second semiconductor region via a gate insulating layer. The fourth semiconductor region is located around the second semiconductor region along a first plane. The fourth semiconductor region is separated from the second semiconductor region. A distance between the second semiconductor region and the fourth semiconductor region is less than a length of the fourth semiconductor region in a second direction. The second electrode is located on the second semiconductor region, the third semiconductor region, and the gate electrode, and is electrically connected to the second and third semiconductor regions.

### CROSS-REFERENCE TO RELATED APPLICATIONS

This application is based upon and claims the benefit of priority from Japanese Patent Application No.2025-048590, filed on Mar. 24, 2025; the entire contents of which are incorporated herein by reference.

### FIELD

Embodiments of the invention relate generally to a semiconductor device.

### BACKGROUND

Semiconductor devices such as metal-oxide-semiconductor field-effect transistors (MOSFETs) are used in applications such as, for example, power conversion. It is desirable to reduce the switching loss of such a semiconductor device.

### BRIEF DESCRIPTION OF THE DRAWINGS

FIG. 1 is a plan view showing a semiconductor device according to an embodiment;

FIG. 2 is a II-II cross-sectional view of FIG. 1;

FIG. 3 is a III-III cross-sectional view of FIG. 1;

FIG. 4 is a IV-IV cross-sectional view of FIG. 1;

FIG. 5 is a plan view showing the semiconductor device according to the embodiment;

FIG. 6 is a cross-sectional view showing a portion of a semiconductor device according to a reference example;

FIG. 7 is a partially enlarged cross-sectional view of FIG. 2;

FIG. 8 is a cross-sectional view showing a portion of a semiconductor device according to a first modification of the embodiment;

FIG. 9 is a cross-sectional view showing a portion of a semiconductor device according to a second modification of the embodiment; and

FIG. 10 is a cross-sectional view showing a portion of a semiconductor device according to a third modification of the embodiment.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a gate electrode, a fourth semiconductor region of the second conductivity type, and a second electrode. The first semiconductor region is located on the first electrode. The second semiconductor region is located on the first semiconductor region. The third semiconductor region is located on the second semiconductor region. The gate electrode faces the second semiconductor region via a gate insulating layer. The fourth semiconductor region is located around the second semiconductor region along a first plane perpendicular to a first direction, the first direction being from the first electrode toward the first semiconductor region. The fourth semiconductor region is separated from the second semiconductor region. A distance between the second semiconductor region and the fourth semiconductor region is less than a length of the fourth semiconductor region in a second direction, the second direction being from the second semiconductor region toward the fourth semiconductor region. The second electrode is located on the second semiconductor region, the third semiconductor region, and the gate electrode, and is electrically connected to the second and third semiconductor regions.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

In the following descriptions and drawings, notations of n⁺, n⁻, and p represent relative heights of impurity concentrations. That is, the notation with “+” shows a relatively higher impurity concentration than an impurity concentration for the notation without any of “+” and “-”. The notation with “-” shows a relatively lower impurity concentration than the impurity concentration for the notation without any of them. These notations represent relative height of a net impurity concentration after mutual compensation of these impurities when respective regions include both of a p-type impurity and an n-type impurity.

The embodiments described below may be implemented by reversing the p-type and the n-type of the semiconductor regions.

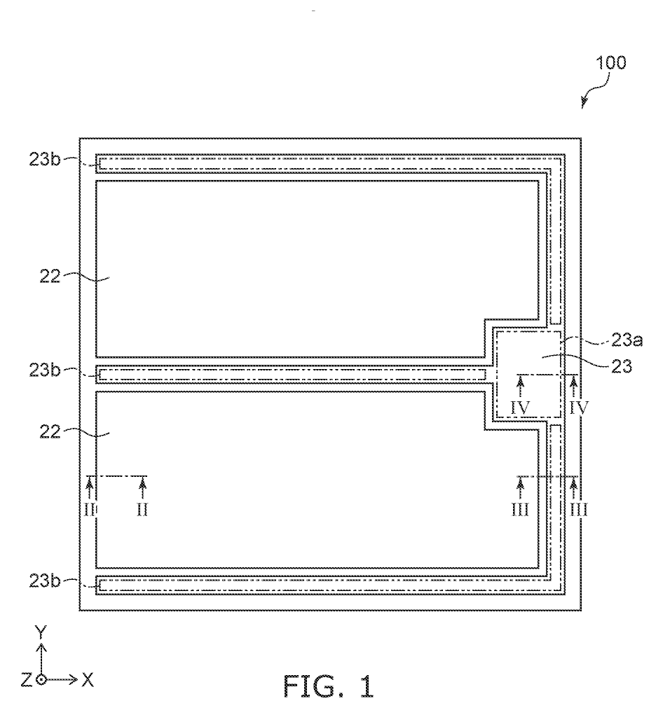

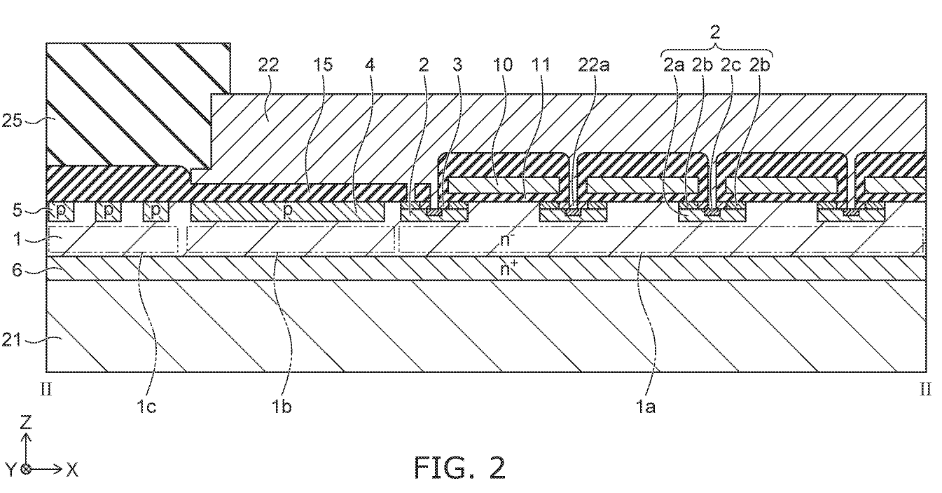

FIG. 1 is a plan view showing a semiconductor device according to an embodiment. FIGS. 2 to 4 are respectively a II-II cross-sectional view, a III-III cross-sectional view, and a IV-IV cross-sectional view of FIG. 1.

The semiconductor device 100 according to the embodiment is a MOSFET. As shown in FIGS. 1 to 4, the semiconductor device 100 includes an n⁻-type drift region 1 (a first semiconductor region), a p-type base region 2 (a second semiconductor region), an n⁺-type source region 3 (a third semiconductor region), a p-type semiconductor region 4 (a fourth semiconductor region), a p-type guard ring region 5 (a fifth semiconductor region), an n⁺-type drain region 6, a gate electrode 10, a conductive layer 13, an insulating layer 15, a drain electrode 21 (a first electrode), a source electrode 22 (a second electrode), a gate pad 23 (a third electrode), and a resin part 25. The n-type is an example of a first conductivity type. The p-type is an example of a second conductivity type.

An XYZ orthogonal coordinate system is used in the description of embodiments. The direction from the drain electrode 21 toward the n⁻-type drift region 1 is referred to as a Z-direction (a first direction). Two mutually-orthogonal directions perpendicular to the Z-direction are referred to as an X-direction (a second perpendicular direction) and a Y-direction (a first perpendicular direction). In the description, the direction from the drain electrode 21 toward the n⁻-type drift region 1 is referred to as "up" or "above", and the opposite direction is referred to as "down" or "below". These directions are based on the relative positional relationship between the drain electrode 21 and the n⁻-type drift region 1 and are independent of the direction of gravity.

As shown in FIG. 1, the source electrode 22 and the gate pad 23 are located at the upper surface of the semiconductor device 100. The source electrode 22 and the gate pad 23 are separated from each other and are electrically isolated from each other.

The gate pad 23 includes a pad part 23a and a wiring part 23b. The pad part 23a spreads along the X-Y plane. For example, a wire is bonded to the pad part 23a when the semiconductor device 100 is mounted to an external electrical circuit. The wiring part 23b is located around the source electrode 22 along the X-Y plane. In the illustrated example, multiple source electrodes 22 are arranged in the Y-direction. The source electrodes 22 and the wiring part 23b that extends in the X-direction are alternately arranged in the Y-direction.

As shown in FIGS. 2 to 4, the drain electrode 21 is located at the lower surface of the semiconductor device 100. The n⁺-type drain region 6 is located on the drain electrode 21 and electrically connected to the drain electrode 21.

The n⁻-type drift region 1 is located on the n⁺-type drain region 6 and electrically connected to the drain electrode 21 via the n⁺-type drain region 6. The n-type impurity concentration of the n⁻-type drift region 1 is less than the n-type impurity concentration of the n⁺-type drain region 6.

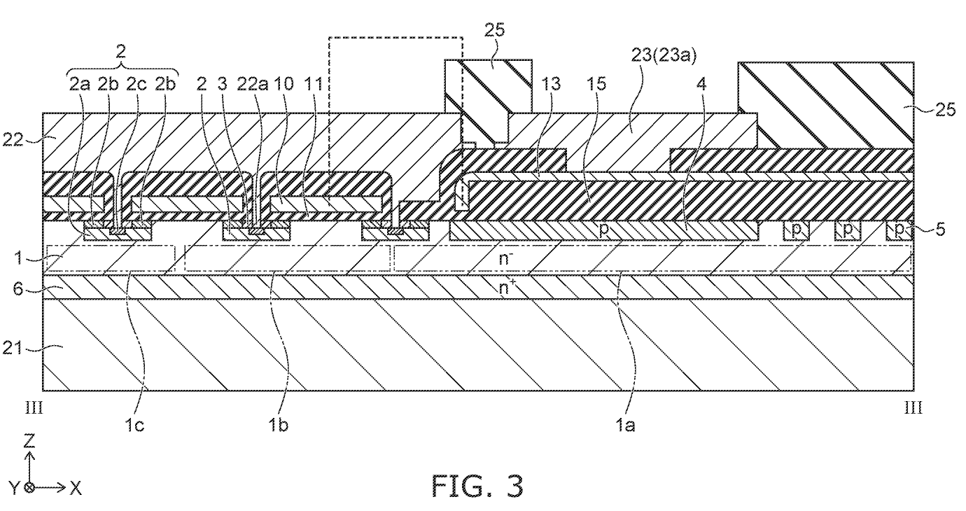

As shown in FIGS. 2 and 3, the p-type base region 2 is located on the n⁻-type drift region 1. The n⁺-type source region 3 is located on the p-type base region 2.

The gate electrode 10 is located on the p-type base region 2 with a gate insulating layer 11 interposed. The gate electrode 10 faces a portion of the n⁺-type source region 3, the p-type base region 2, and a portion of the n⁻-type drift region 1 via the gate insulating layer 11.

The p-type semiconductor region 4 is located around the n⁺-type source region 3 along the X-Y plane. The p-type semiconductor region 4 is separated from the p-type base region 2. The p-type impurity concentration of the p-type semiconductor region 4 may be equal to or less than the p-type impurity concentration of the p-type base region 2.

The p-type guard ring region 5 is located around the p-type semiconductor region 4 along the X-Y plane. The p-type guard ring region 5 is separated from the p-type semiconductor region 4. The p-type impurity concentration of the p-type guard ring region 5 may be equal to or less than the p-type impurity concentration of the p-type semiconductor region 4.

The source electrode 22 is positioned on the p-type base region 2, the n⁺-type source region 3, and the gate electrode 10 and is electrically connected to the p-type base region 2 and the n⁺-type source region 3. The source electrode 22 is electrically isolated from the gate electrode 10. The insulating layer 15 is located between the p-type semiconductor region 4 and the source electrode 22; and the p-type semiconductor region 4 does not directly contact the source electrode 22. For example, the entire p-type semiconductor region 4 is covered with the insulating layer 15 when viewed along the Z-direction.

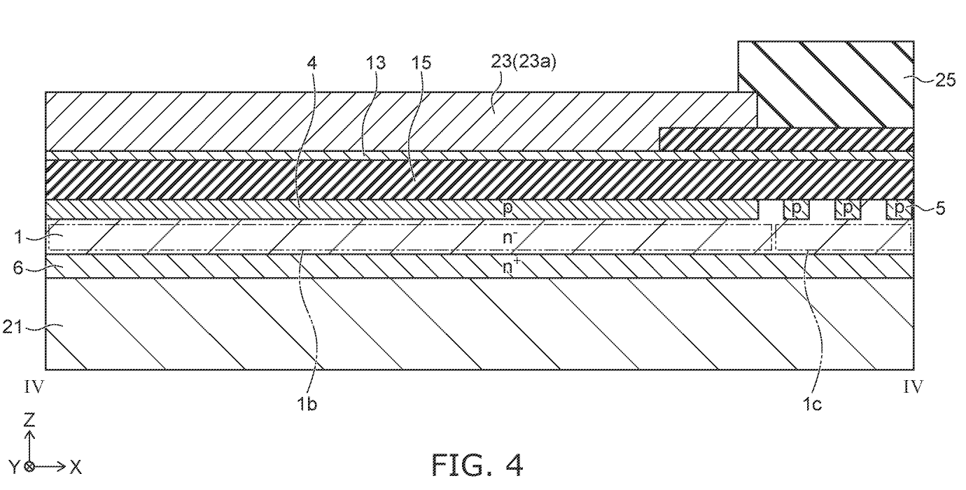

As shown in FIGS. 3 and 4, the gate pad 23 is positioned on the p-type semiconductor region 4 with the insulating layer 15 interposed. The conductive layer 13 is located inside the insulating layer 15. The gate electrode 10 is electrically connected to the conductive layer 13 as illustrated by the broken line in FIG. 3. The conductive layer 13 contacts the pad part 23a of the gate pad 23. Specifically, the gate electrode 10 is electrically connected to the gate pad 23 via the conductive layer 13.

As shown in FIGS. 2 to 4, the region between the source electrode 22 and the gate pad 23 and the outer perimeter of the upper surface of the semiconductor device 100 are covered with the resin part 25. The resin part 25 is electrically insulative.

As shown in FIGS. 2 and 3, multiple p-type base regions 2 and multiple gate electrodes 10 are arranged in the X-direction. A pair of n⁺-type source regions 3 is separated from each other in the X-direction on one p-type base region 2. The source electrode 22 includes a contact part 22a extending downward. The lower portion of the contact part 22a is positioned between the pair of n⁺-type source regions 3. The contact part 22a contacts the p-type base region 2 and the pair of n⁺-type source regions 3.

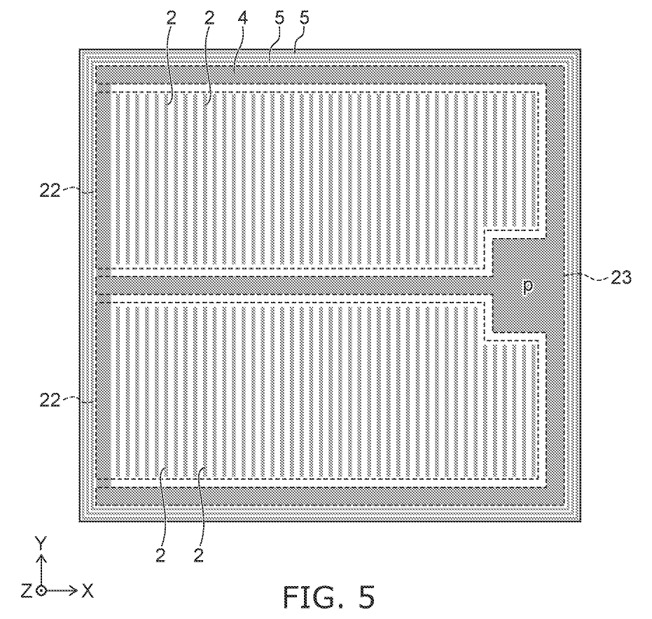

FIG. 5 is a plan view showing the semiconductor device according to the embodiment. The n⁺-type source region 3, the gate electrode 10, the insulating layer 15, the source electrode 22, the gate pad 23, and the resin part 25 are not illustrated in FIG. 5.

As shown in FIG. 5, the source electrode 22 is positioned on the multiple p-type base regions 2 and on a portion of the p-type semiconductor region 4. The p-type semiconductor region 4 is located around the multiple p-type base regions 2 along the X-Y plane. Multiple p-type guard ring regions 5 are arranged in the direction from the p-type semiconductor region 4 toward the p-type guard ring region 5. The multiple p-type guard ring regions 5 are separated from each other. A portion of the source electrode 22 and the gate pad 23 are positioned on the p-type semiconductor region 4.

Examples of the materials of the components will now be described.

The n⁻-type drift region 1, the p-type base region 2, the n⁺-type source region 3, the p-type semiconductor region 4, the p-type guard ring region 5, and the n⁺-type drain region 6 include silicon, silicon carbide, gallium nitride, or gallium arsenide as a semiconductor material. In particular, silicon carbide is favorable as the semiconductor material from the perspective of increasing the breakdown voltage and reducing the electrical resistance of the semiconductor device 100. When silicon carbide is used as the semiconductor material, nitrogen or phosphorus can be used as the n-type impurity. Aluminum or boron can be used as the p-type impurity. The gate electrode 10 and the conductive layer 13 include polysilicon to which an impurity is added. The gate insulating layer 11 and the insulating layer 15 include insulating materials such as silicon oxide, silicon nitride, silicon oxynitride, etc. The drain electrode 21, the source electrode 22, and the gate pad 23 include metal materials such as aluminum, copper, etc. The resin part 25 includes an insulating resin such as polyimide, etc.

Operations of the semiconductor device 100 will now be described.

When a voltage that is not less than a threshold is applied to the gate electrode 10, a channel (an inversion layer) is formed in the p-type base region 2. When the channel is formed in a state in which the potential of the drain electrode 21 is higher than the potential of the source electrode 22, electrons flow from the source electrode 22 toward the drain electrode 21 via the channel. As a result, the semiconductor device 100 is set to an on-state. When the voltage applied to the gate electrode 10 drops below the threshold, the channel in the p-type base region 2 disappears, and the semiconductor device 100 is switched to an off-state.

As shown in FIGS. 2 and 3, the p-type base region 2 may include a first region 2a, a second region 2b, and a third region 2c. The second region 2b is positioned between the first region 2a and the contact part 22a. The third region 2c is positioned between the n⁺-type source region 3 and the n⁻-type drift region 1 in the X-direction. The p-type impurity concentrations of the second region 2b and the third region 2c are greater than the p-type impurity concentration of the first region 2a. By increasing the p-type impurity concentration of the second region 2b, the electrical resistance between the p-type base region 2 and the source electrode 22 can be reduced. By increasing the p-type impurity concentration of the third region 2c, a threshold voltage for switching the semiconductor device 100 between the off-state and the on-state can be adjusted.

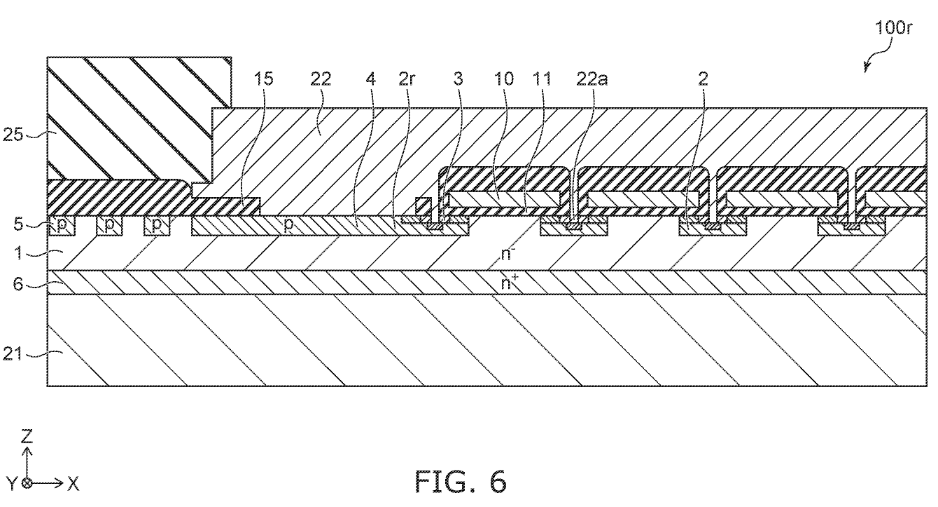

FIG. 6 is a cross-sectional view showing a portion of a semiconductor device according to a reference example.

The semiconductor device 100r shown in FIG. 6 does not include the p-type semiconductor region 4. A p-type base region 2r is located at the outermost perimeter of the multiple p-type base regions 2. The X-direction length of the p-type base region 2r is greater than the X-direction lengths of the other p-type base regions 2. The p-type base region 2r is electrically connected to the source electrode 22. By including the p-type base region 2r, the depletion layer spreads more easily from the p-type base region 2r toward the outer perimeter of the semiconductor device 100 when the semiconductor device 100r is in the off-state. As a result, the breakdown voltage of the semiconductor device 100r can be increased.

An output charge amount Qoss is one indicator of the characteristics of the semiconductor device. The switching loss of the semiconductor device decreases as the output charge amount Qoss decreases. The output charge amount Qoss has a relationship with a capacitance Cds between the drain electrode 21 and the source electrode 22. The output charge amount Qoss increases as the capacitance Cds increases. In the semiconductor device 100r, the p-type base region 2r that is larger than each p-type base region 2 is located at the outermost perimeter of the multiple p-type base regions 2. The p-type base region 2r is electrically connected to the source electrode 22. Therefore, the capacitance Cds is increased by the amount of the capacitance between the n⁻-type drift region 1 and the p-type base region 2r.

In the semiconductor device 100, the p-type semiconductor region 4 is separated from the p-type base region 2. The insulating layer 15 is located between the p-type semiconductor region 4 and the source electrode 22; and the p-type semiconductor region 4 does not directly contact the source electrode 22. Therefore, the contribution to the capacitance Cds of the capacitance between the n⁻-type drift region 1 and the p-type semiconductor region 4 can be reduced. According to the semiconductor device 100, the capacitance Cds can be less than that of the semiconductor device 100r. As a result, the output charge amount Qoss can be reduced, and the switching loss of the semiconductor device 100 can be reduced.

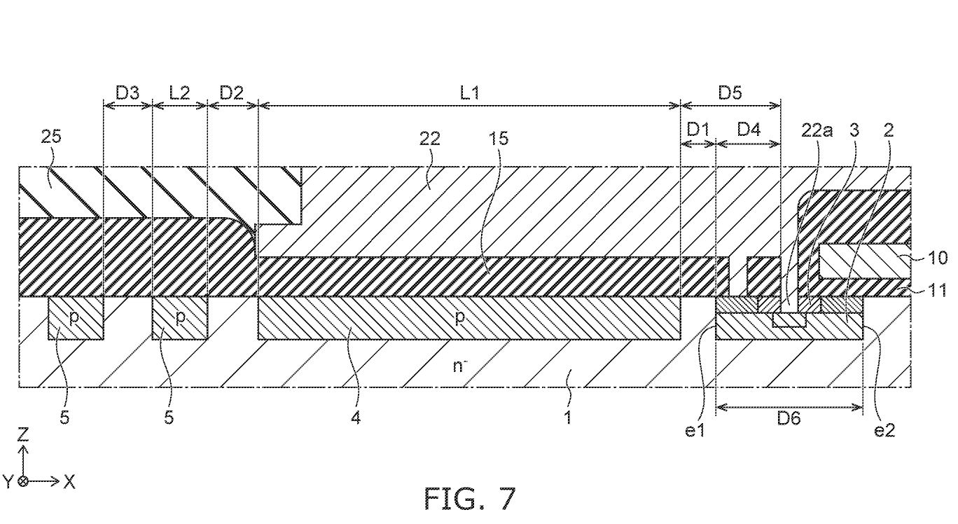

FIG. 7 is a partially enlarged cross-sectional view of FIG. 2.

In the semiconductor device 100 according to the embodiment as shown in FIG. 7, a distance D1 between the p-type base region 2 and the p-type semiconductor region 4 in the X-direction is less than a length L1 of the p-type semiconductor region 4 in the outward direction (the second direction) from the p-type base region 2 toward the p-type semiconductor region 4. In other words, in the semiconductor device 100, the p-type base region 2 and the p-type semiconductor region 4 are proximate to each other so that the distance D1 is less than the length L1. The outward direction is parallel to the X-direction in the cross section shown in FIG. 7. As long as the distance D1 is less than the length L1, the potential of the p-type semiconductor region 4 is affected by the potential of the p-type base region 2. When the semiconductor device 100 is in the off-state, the depletion layer also can spread from the p-n junction between the n⁻-type drift region 1 and the p-type semiconductor region 4. Therefore, even when the p-type semiconductor region 4 is separated from the p-type base region 2, spreading of the depletion layer toward the outer perimeter of the semiconductor device 100 can be promoted, and a reduction of the breakdown voltage of the semiconductor device 100 can be suppressed.

According to the embodiment, the switching loss of the semiconductor device 100 can be reduced while suppressing a reduction of the breakdown voltage of the semiconductor device 100.

For example, from the perspective of increasing the breakdown voltage of the semiconductor device 100, it is favorable for the distance D1 between the p-type base region 2 and the p-type semiconductor region 4 to be not less than 0.5 μm and not more than 1.5 μm.

It is favorable for the distance D1 to be as short as possible without the p-type base region 2 and the p-type semiconductor region 4 directly contacting each other. The effects of the potential of the p-type semiconductor region 4 on the potential of the p-type base region 2 increase as the distance D1 decreases. As a result, the breakdown voltage of the semiconductor device 100 can be further increased. The region in which the p-type semiconductor region 4 is located is an ineffective region in which a current does not flow. To downsize the semiconductor device 100, a short length L1 is favorable. From the perspective of downsizing and increasing the breakdown voltage, it is favorable for the distance D1 to be less than 0.5 times the length L1, and more favorably less than 0.3 times the length L1.

The p-type semiconductor region 4 is positioned under the source electrode 22 with the insulating layer 15 interposed. By locating the p-type semiconductor region 4 under the source electrode 22, compared to when the p-type semiconductor region 4 is not included, the electric field intensity at the outer perimeter end of the source electrode 22 can be relaxed, and the occurrence of dielectric breakdown can be suppressed. In other words, by including the p-type semiconductor region 4, the size of the source electrode 22 in the X-Y plane can be increased while suppressing the occurrence of dielectric breakdown at the outer perimeter vicinity of the source electrode 22. As a result, the arrangement degree of freedom when an external terminal (a leadframe, a wire, or the like) is connected to the source electrode 22 can be increased while reducing the electrical resistance of the source electrode 22.

In the semiconductor device 100, the p-type guard ring region 5 that is located at the periphery of the p-type semiconductor region 4 may be omitted. However, from the perspective of increasing the breakdown voltage, it is favorable to include the p-type guard ring region 5. By including one or more p-type guard ring regions 5, the depletion layer spreads more easily toward the outer perimeter of the semiconductor device 100. As a result, the breakdown voltage of the semiconductor device 100 can be further increased.

The length L1 of the p-type semiconductor region 4 in the outward direction is greater than a length L2 of the p-type guard ring region 5 in the outward direction. The p-type semiconductor region 4 is positioned further inward in the semiconductor device 100 than the p-type guard ring region 5. When the semiconductor device 100 is in the off-state, a larger voltage is applied to the p-n junction between the n⁻-type drift region 1 and the p-type semiconductor region 4 than the p-n junction between the n⁻-type drift region 1 and the p-type guard ring region 5. By setting the length L1 to be greater than the length L2, the p-type semiconductor region 4 is less likely to be completely depleted, and the breakdown voltage of the semiconductor device 100 can be more stable. For example, it is favorable for the length L1 to be not less than 3 times and not more than 20 times the length L2.

The length L2 of the p-type guard ring region 5 in the outward direction is less than the length L1 of the p-type semiconductor region 4 in the outward direction. A distance D2 between the p-type semiconductor region 4 and the p-type guard ring region 5 is less than the length L1 of the p-type semiconductor region 4.

A distance D3 between the p-type guard ring regions 5 is less than the length L1 of the p-type semiconductor region 4. The distance D3 may be equal to or different from the distance D2 between the p-type semiconductor region 4 and the p-type guard ring region 5. The distance D3 may be equal to or different from the length L2 of the p-type guard ring region 5.

The p-type base region 2 includes a first end e1 and a second end e2 in the X-direction. The first end e1 is positioned between the second end e2 and the p-type semiconductor region 4 in the X-direction. For example, a distance D4 between the contact part 22a and the first end e1 is less than the length L1 of the p-type semiconductor region 4. The distance D1 may be less than the distance D4.

For example, a distance D5 between the contact part 22a and the p-type semiconductor region 4 is less than the length L1 of the p-type semiconductor region 4. A distance D6 between the first end e1 and the second end e2 is less than the length L1.

As shown in FIGS. 2 to 4, the n⁻-type drift region 1 may include a first part 1a, a second part 1b, and a third part 1c. The second part 1b is located around the first part 1a along the X-Y plane. The third part 1c is located around the second part 1b along the X-Y plane. The p-type base region 2 and the gate electrode 10 are positioned on the first part 1a. The p-type semiconductor region 4 is positioned on the second part 1b. The p-type guard ring region 5 is positioned on the third part 1c. The n-type impurity concentration of the first part 1a is greater than the n-type impurity concentration of the second part 1b and greater than the n-type impurity concentration of the third part 1c.

At turn-off of the semiconductor device 100, breakdown may occur where the electric field intensity is high. When breakdown occurs, electrons are discharged from the drain electrode 21, and holes are discharged from the source electrode 22. When the p-type semiconductor region 4 does not directly contact the source electrode 22, holes concentrate and flow toward the p-type base region 2 at the outermost perimeter when breakdown occurs at the outer perimeter vicinity of the n⁻-type drift region 1. The semiconductor device 100 includes a parasitic transistor including the n⁻-type drift region 1, the p-type base region 2, and the n⁺-type source region 3. When holes concentrate and flow toward some of the p-type base regions 2, there is a possibility that the potential of the p-type base region 2 may increase and the parasitic transistor may operate. When the n-type impurity concentration of the first part 1a is greater than the n-type impurity concentration of the second part 1b, the electric field intensity of the first part 1a increases easily compared to the second part 1b. Therefore, compared to the second part 1b, breakdown occurs more easily at the first part 1a. When breakdown occurs at the first part 1a, the holes disperse and flow to the multiple p-type base regions 2. The holes can be prevented from flowing concentratively to some of the p-type base regions 2; and the operation of the parasitic transistor can be suppressed thereby.

To make it easy for breakdown to occur at the first part 1a, it is favorable for the n-type impurity concentration of the first part 1a to be not less than 2 times the n-type impurity concentration of the second part 1b. On the other hand, when the n-type impurity concentration of the first part 1a is too high, the breakdown voltage of the semiconductor device 100 may be reduced. It is therefore favorable for the n-type impurity concentration of the first part 1a to be not less than 2 times and not more than 10 times the n-type impurity concentration of the second part 1b.

The embodiment of the invention is more favorable when the semiconductor device 100 includes silicon carbide as the semiconductor material. Compared to silicon devices, faster switching characteristics are desirable in so-called SiC devices using silicon carbide. As the switching speed increases, the effects on the output charge amount Qoss increase, and the switching loss increases. By applying the embodiment to a SiC device, the switching loss of the semiconductor device 100 can be effectively reduced.

### First modification

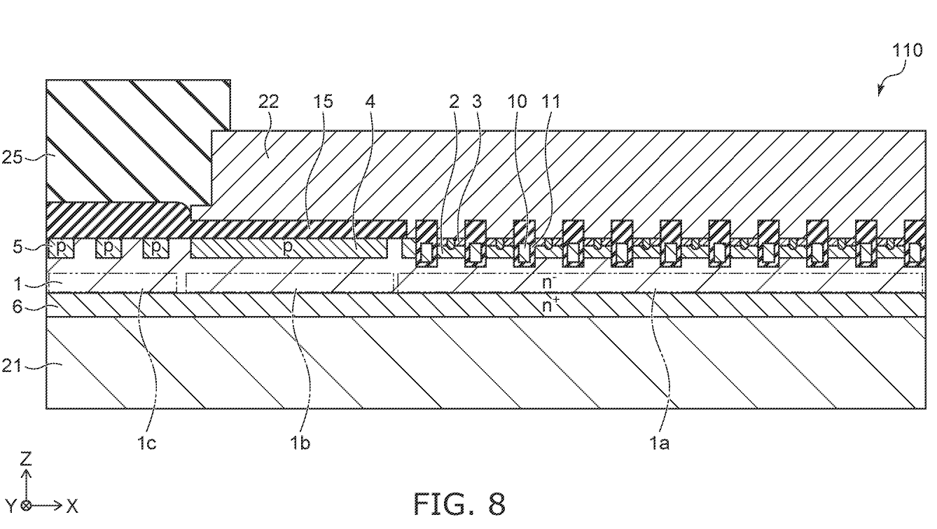

FIG. 8 is a cross-sectional view showing a portion of a semiconductor device according to a first modification of the embodiment.

The semiconductor device 110 shown in FIG. 8 differs from the semiconductor device 100 mainly in the structure of the gate electrode 10. The semiconductor device 100 has a so-called planar structure in which the gate electrode 10 is located on the p-type base region 2 and spreads along the X-Y plane. The semiconductor device 110 has a so-called trench structure in which the gate electrode 10 is located in a trench formed in a semiconductor region.

Specifically, the gate electrode 10 faces the p-type base region 2 via the gate insulating layer 11 in the X-direction. A pair of n⁺-type source regions 3 is separated from each other in the X-direction on the p-type base region 2. For example, a portion of the p-type base region 2 is positioned between the pair of n⁺-type source regions 3. The p-type impurity concentration of the portion of the p-type base region 2 is greater than the p-type impurity concentration of the other portions of the p-type base region 2. The portion of the p-type base region 2 and the pair of n⁺-type source regions 3 contact the source electrode 22.

Otherwise, the structure of the semiconductor device 100 is applicable to the structure of the semiconductor device 110. For example, similarly to the semiconductor device 100, the source electrode 22 and the gate pad 23 are located at the upper surface of the semiconductor device 110. The gate pad 23 is electrically connected to the gate electrode 10 via the conductive layer 13 inside the insulating layer 15. The insulating layer 15 is located between the p-type semiconductor region 4 and the source electrode 22; and the p-type semiconductor region 4 does not directly contact the source electrode 22.

In the semiconductor device 110 as well, similarly to the semiconductor device 100, the p-type semiconductor region 4 is separated from the p-type base region 2. The contribution to the capacitance Cds of the capacitance between the n⁻-type drift region 1 and the p-type semiconductor region 4 can be reduced. As a result, the output charge amount Qoss can be reduced, and the switching loss of the semiconductor device 110 can be reduced.

### Second modification

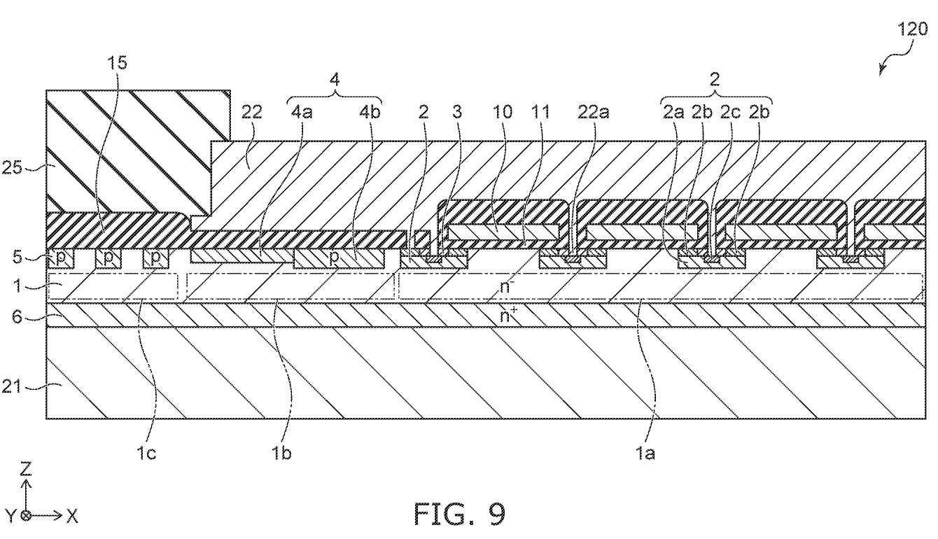

FIG. 9 is a cross-sectional view showing a portion of a semiconductor device according to a second modification of the embodiment. The structure of the p-type semiconductor region 4 of the semiconductor device 120 shown in FIG. 9 is different from that of the semiconductor device 100 shown in FIGS. 1 to 5.

In the semiconductor device 120, the p-type semiconductor region 4 includes an outer perimeter part 4a and an inner perimeter part 4b. The outer perimeter part 4a and the inner perimeter part 4b are positioned around the p-type base region 2 along the X-Y plane. The inner perimeter part 4b is positioned between the p-type base region 2 and the outer perimeter part 4a. The p-type impurity concentration of the outer perimeter part 4a is less than the p-type impurity concentration of the inner perimeter part 4b. As shown in FIG. 9, the thickness (the dimension in the Z-direction) of the outer perimeter part 4a may be less than the thickness of the inner perimeter part 4b.

By providing the outer perimeter part 4a and the inner perimeter part 4b with mutually-different p-type impurity concentrations, the depletion layer can spread toward the outer perimeter of the semiconductor device 120; and the electric field intensity at the vicinity of the outer perimeter end of the p-type semiconductor region 4 can be reduced. According to the second modification, compared to the semiconductor device 100, the breakdown voltage of the semiconductor device 120 can be further increased.

### Third modification

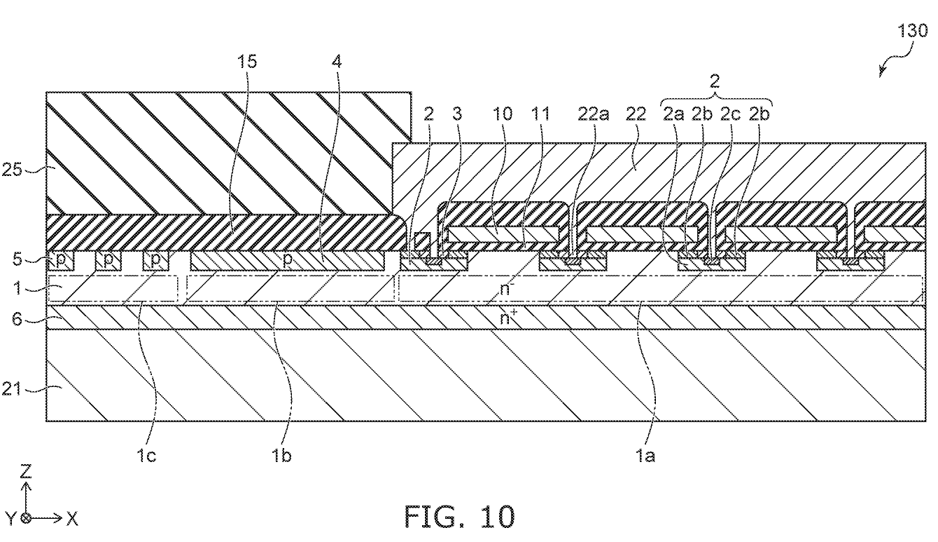

FIG. 10 is a cross-sectional view showing a portion of a semiconductor device according to a third modification of the embodiment. The structure of the source electrode 22 of the semiconductor device 130 shown in FIG. 10 is different from that of the semiconductor device 100 shown in FIGS. 1 to 5.

Specifically, in the semiconductor device 130, the source electrode 22 is not located on the p-type semiconductor region 4. The insulating layer 15 and the resin part 25 are located in the region above the p-type semiconductor region 4.

In the semiconductor device according to the embodiment, the p-type semiconductor region 4 and the source electrode 22 do not contact each other. It is unnecessary for the source electrode 22 to be located on the p-type semiconductor region 4 as in the semiconductor device 100r shown in FIG. 6. Therefore, the source electrode 22 can be omitted above the p-type semiconductor region 4.

The embodiments of the invention include the following features.

### Feature 1

A semiconductor device, including:

a first electrode;

a first semiconductor region located on the first electrode, the first semiconductor region being of a first conductivity type;

a second semiconductor region located on the first semiconductor region, the second semiconductor region being of a second conductivity type;

a third semiconductor region located on the second semiconductor region, the third semiconductor region being of the first conductivity type;

a gate electrode facing the second semiconductor region via a gate insulating layer;

a fourth semiconductor region located around the second semiconductor region along a first plane perpendicular to a first direction, the first direction being from the first electrode toward the first semiconductor region, the fourth semiconductor region being separated from the second semiconductor region, the fourth semiconductor region being of the second conductivity type, a distance between the second semiconductor region and the fourth semiconductor region being less than a length of the fourth semiconductor region in a second direction, the second direction being from the second semiconductor region toward the fourth semiconductor region; and

a second electrode located on the second semiconductor region, the third semiconductor region, and the gate electrode, the second electrode being electrically connected to the second and third semiconductor regions.

### Feature 2

The device according to feature 1, in which

the distance between the second semiconductor region and the fourth semiconductor region is less than 0.5 times the length of the fourth semiconductor region.

### Feature 3

The device according to feature 1 or 2, further including:

a fifth semiconductor region located around the fourth semiconductor region along the first plane,

the fifth semiconductor region being separated from the fourth semiconductor region,

the fifth semiconductor region being of the second conductivity type.

### Feature 4

The device according to feature 3, in which

a length of the fifth semiconductor region in the second direction is less than the length of the fourth semiconductor region in the second direction.

### Feature 5

The device according to feature 3 or 4, in which

a plurality of the fifth semiconductor regions are arranged in the second direction.

### Feature 6

The device according to feature 5, in which

a distance between adjacent fifth semiconductor regions among the plurality of fifth semiconductor regions is less than the length of the fourth semiconductor region in the second direction.

### Feature 7

The device according to any one of features 1 to 6, in which

the fourth semiconductor region includes:

an outer perimeter part positioned around the second semiconductor region along the first plane; and

an inner perimeter part positioned between the second semiconductor region and the outer perimeter part, and

a second-conductivity-type impurity concentration of the outer perimeter part is less than a second-conductivity-type impurity concentration of the inner perimeter part.

### Feature 8

The device according to any one of features 1 to 7, further including:

a third electrode located on the fourth semiconductor region with an insulating layer interposed,

the third electrode being electrically connected to the gate electrode.

### Feature 9

The device according to feature 8, in which

a portion of the second electrode is located on the fourth semiconductor region with the insulating layer interposed.

### Feature 10

The device according to feature 8 or 9, in which

a plurality of the second electrodes are arranged in a first perpendicular direction,

the first perpendicular direction is perpendicular to the first direction,

a portion of the third electrode is located between the plurality of second electrodes, and

a portion of the fourth semiconductor region is positioned under the portion of the third electrode with the insulating layer interposed.

### Feature 11

The device according to feature 8 or 9, in which

a plurality of second electrodes are arranged in a first perpendicular direction,

the first perpendicular direction is perpendicular to the first direction,

the third electrode includes a wiring part extending in a second perpendicular direction,

the second perpendicular direction is perpendicular to the first direction and the first perpendicular direction,

the plurality of second electrodes and the wiring part are alternately arranged in the first perpendicular direction, and

a portion of the fourth semiconductor region is positioned under a plurality of the wiring parts with the insulating layer interposed.

### Feature 12

The device according to any one of features 1 to 11, in which

a plurality of the second semiconductor regions and a plurality of the gate electrodes are arranged in a second perpendicular direction,

the second perpendicular direction is perpendicular to the first direction, and

the fourth semiconductor region is located around the plurality of second semiconductor regions along the first plane.

### Feature 13

The device according to feature 12, in which

one of the plurality of second semiconductor regions is adjacent to the fourth semiconductor region in the second perpendicular direction with a portion of the first semiconductor region interposed,

a pair of the third semiconductor regions is separated from each other in the second perpendicular direction on the one of the plurality of second semiconductor regions, and

the second electrode includes a contact part positioned between the pair of the third semiconductor regions.

### Feature 14

The device according to feature 13, in which

the one of the plurality of second semiconductor regions includes a first end and a second end in the second perpendicular direction,

the first end is positioned between the fourth semiconductor region and the second end, and

a distance between the contact part and the first end in the second perpendicular direction is less than the length of the fourth semiconductor region in the second direction.

### Feature 15

The device according to feature 14, in which

a distance between the contact part and the fourth semiconductor region in the second perpendicular direction is less than the length of the fourth semiconductor region in the second direction.

### Feature 16

The device according to feature 14, in which

a distance between the first end and the second end in the second perpendicular direction is less than the length of the fourth semiconductor region in the second direction.

### Feature 17

The device according to any one of features 12 to 16, in which

the second electrode is located on the plurality of second semiconductor regions and a plurality of the fourth semiconductor regions.

### Feature 18

The device according to any one of features 1 to 17, in which

the first semiconductor region includes:

a first part; and

a second part located around the first part along the first plane,

the second semiconductor region is located on the first part,

the fourth semiconductor region is located on the second part, and

a first-conductivity-type impurity concentration of the first part is greater than a first-conductivity-type impurity concentration of the second part.

### Feature 19

The device according to feature 18, in which

the first-conductivity-type impurity concentration of the first part is not less than 2 times and not more than 10 times the first-conductivity-type impurity concentration of the second part.

### Feature 20

The device according to any one of features 1 to 19, in which

the first to fourth semiconductor regions include silicon carbide.

According to the embodiments described above, a semiconductor device that can reduce the switching loss while suppressing a reduction of the breakdown voltage is provided.

In the specification, “or” shows that “at least one” of items listed in the sentence can be adopted.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region located on the second semiconductor region, the third semiconductor region being of the first conductivity type;
a gate electrode facing the second semiconductor region via a gate insulating layer;
a fourth semiconductor region located around the second semiconductor region along a first plane perpendicular to a first direction, the first direction being from the first electrode toward the first semiconductor region, the fourth semiconductor region being separated from the second semiconductor region, the fourth semiconductor region being of the second conductivity type, a distance between the second semiconductor region and the fourth semiconductor region being less than a length of the fourth semiconductor region in a second direction, the second direction being from the second semiconductor region toward the fourth semiconductor region; and
a second electrode located on the second semiconductor region, the third semiconductor region, and the gate electrode, the second electrode being electrically connected to the second and third semiconductor regions.

2. The device according to claim 1, wherein
the distance between the second semiconductor region and the fourth semiconductor region is less than 0.5 times the length of the fourth semiconductor region.

3. The device according to claim 1, further comprising:
a fifth semiconductor region located around the fourth semiconductor region along the first plane,
the fifth semiconductor region being separated from the fourth semiconductor region,
the fifth semiconductor region being of the second conductivity type.

4. The device according to claim 3, wherein
a length of the fifth semiconductor region in the second direction is less than the length of the fourth semiconductor region in the second direction.

5. The device according to claim 3, wherein
a plurality of the fifth semiconductor regions are arranged in the second direction.

6. The device according to claim 5, wherein
a distance between adjacent fifth semiconductor regions among the plurality of fifth semiconductor regions is less than the length of the fourth semiconductor region in the second direction.

7. The device according to claim 1, wherein
the fourth semiconductor region includes:
an outer perimeter part positioned around the second semiconductor region along the first plane; and
an inner perimeter part positioned between the second semiconductor region and the outer perimeter part, and
a second-conductivity-type impurity concentration of the outer perimeter part is less than a second-conductivity-type impurity concentration of the inner perimeter part.

8. The device according to claim 1, further comprising:
a third electrode located on the fourth semiconductor region with an insulating layer interposed,
the third electrode being electrically connected to the gate electrode.

9. The device according to claim 8, wherein
a portion of the second electrode is located on the fourth semiconductor region with the insulating layer interposed.

10. The device according to claim 8, wherein
a plurality of the second electrodes are arranged in a first perpendicular direction,
the first perpendicular direction is perpendicular to the first direction,
a portion of the third electrode is located between the plurality of second electrodes, and
a portion of the fourth semiconductor region is positioned under the portion of the third electrode with the insulating layer interposed.

11. The device according to claim 8, wherein
a plurality of second electrodes are arranged in a first perpendicular direction,
the first perpendicular direction is perpendicular to the first direction,
the third electrode includes a wiring part extending in a second perpendicular direction,
the second perpendicular direction is perpendicular to the first direction and the first perpendicular direction,
the plurality of second electrodes and the wiring part are alternately arranged in the first perpendicular direction, and
a portion of the fourth semiconductor region is positioned under a plurality of the wiring parts with the insulating layer interposed.

12. The device according to claim 1, wherein
a plurality of the second semiconductor regions and a plurality of the gate electrodes are arranged in a second perpendicular direction,
the second perpendicular direction is perpendicular to the first direction, and
the fourth semiconductor region is located around the plurality of second semiconductor regions along the first plane.

13. The device according to claim 12, wherein
one of the plurality of second semiconductor regions is adjacent to the fourth semiconductor region in the second perpendicular direction with a portion of the first semiconductor region interposed,
a pair of the third semiconductor regions is separated from each other in the second perpendicular direction on the one of the plurality of second semiconductor regions, and
the second electrode includes a contact part positioned between the pair of the third semiconductor regions.

14. The device according to claim 13, wherein
the one of the plurality of second semiconductor regions includes a first end and a second end in the second perpendicular direction,
the first end is positioned between the fourth semiconductor region and the second end, and
a distance between the contact part and the first end in the second perpendicular direction is less than the length of the fourth semiconductor region in the second direction.

15. The device according to claim 14, wherein
a distance between the contact part and the fourth semiconductor region in the second perpendicular direction is less than the length of the fourth semiconductor region in the second direction.

16. The device according to claim 14, wherein
a distance between the first end and the second end in the second perpendicular direction is less than the length of the fourth semiconductor region in the second direction.

17. The device according to claim 12, wherein
the second electrode is located on the plurality of second semiconductor regions and a plurality of the fourth semiconductor regions.

18. The device according to claim 1, wherein
the first semiconductor region includes:
a first part; and
a second part located around the first part along the first plane,
the second semiconductor region is located on the first part,
the fourth semiconductor region is located on the second part, and
a first-conductivity-type impurity concentration of the first part is greater than a first-conductivity-type impurity concentration of the second part.

19. The device according to claim 18, wherein
the first-conductivity-type impurity concentration of the first part is not less than 2 times and not more than 10 times the first-conductivity-type impurity concentration of the second part.

20. The device according to claim 1, wherein
the first to fourth semiconductor regions include silicon carbide.
